(19) United States
(12) Patent Application Publication
(10) Pub. No.: US 2024/0339501 A1
(43) Pub. Date: Oct. 10, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Che-Hsien Lin, Tainan City (TW); Te-Chang Hsu, Tainan City (TW); Chun-Jen Huang, Tainan City (TW); Chun-Chia Chen, Tainan City (TW)

(73) Assignee: UNITED MICROELECTRONICS CORP., Hsin-Chu City (TW)

(21) Appl. No.: 18/143,095

(22) Filed: May 4, 2023

(30) Foreign Application Priority Data
Apr. 6, 2023 (TW) 112112858

(51) Int. Cl. H01L 29/08; H01L 29/66; H01L 29/78

(52) U.S. Cl. CPC H01L 29/0847; H01L 29/66795; H01L 29/7851

(57) ABSTRACT

A method for fabricating a semiconductor device includes the steps of forming a gate structure on a substrate, forming a fin-shaped structure on the substrate, forming a gate structure on the fin-shaped structure, removing the fin-shaped structure to form a recess, forming a first epitaxial layer in the recess adjacent to the gate structure, and then forming a second epitaxial layer on the first epitaxial layer. Preferably, the semiconductor device further includes a first protrusion on one side of the first epitaxial layer and a second protrusion on another side of the first epitaxial layer.

### BACKGROUND OF THE INVENTION

### 1. Field of the Invention

The invention relates to a method for fabricating semiconductor device, and more particularly to a method of fabricating epitaxial layer having protrusions.

### 2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the FinFET can be controlled by adjusting the work function of the gate.

However, numerous problems still arise from the integration of fin-shaped structure and epitaxial layer in today's FinFET fabrication and affect current leakage and overall performance of the device. Hence, how to improve the current FinFET process has become an important task in this field.

### SUMMARY OF THE INVENTION

According to an embodiment of the present invention, a method for fabricating a semiconductor device includes the steps of forming a gate structure on a substrate, forming a fin-shaped structure on the substrate, forming a gate structure on the fin-shaped structure, removing the fin-shaped structure to form a recess, forming a first epitaxial layer in the recess adjacent to the gate structure, and then forming a second epitaxial layer on the first epitaxial layer. Preferably, the semiconductor device further includes a first protrusion on one side of the first epitaxial layer and a second protrusion on another side of the first epitaxial layer.

According to another aspect of the present invention, a semiconductor device includes a gate structure on a substrate, a first epitaxial layer adjacent to the gate structure, and a second epitaxial layer on the first epitaxial layer. Preferably, the semiconductor device further includes a first protrusion on one side of the first epitaxial layer and a second protrusion on another side of the first epitaxial layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating a semiconductor device according to an embodiment of the present invention.

### DETAILED DESCRIPTION

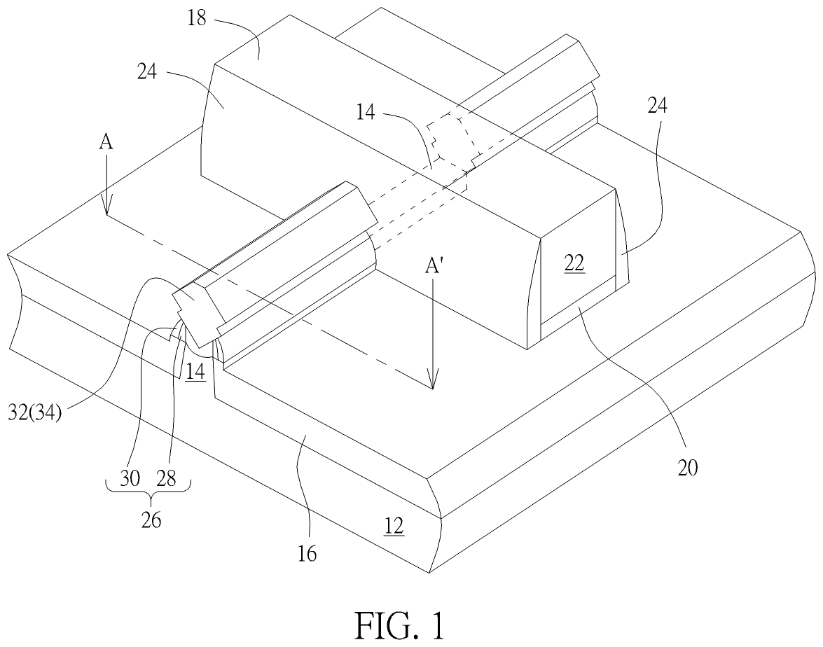

Referring to FIGS. 1-4, FIGS. 1-4 illustrate a method for fabricating a semiconductor device according to an embodiment of the present invention. As shown in FIG. 1, a substrate 12 such as a silicon substrate or silicon-on-insulator (SOI) substrate is first provided and at least a transistor region such as a NMOS region or a PMOS region is defined on the substrate 12. At least a fin-shaped structure 14 and an insulating layer (not shown) is formed on the substrate 12, in which the bottom of the fin-shaped structure 14 is surrounded by the insulating layer made of silicon oxide to form a shallow trench isolation 16. At least a dummy gate or gate structure 18 is then formed on the fin-shaped structure 14.

Preferably, the fin-shaped structure 14 of this embodiment could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 14 could also be obtained by first forming a patterned mask (not shown) on the substrate, 12, and through an etching process, the pattern of the patterned mask is transferred to the substrate 12 to form the fin-shaped structure 14. Moreover, the formation of the fin-shaped structure 14 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure 14. These approaches for forming fin-shaped structure are all within the scope of the present invention.

In this embodiment, the formation of the gate structure 18 could be accomplished by a gate first process, a high-k first approach from gate last process, or a high-k last approach from gate last process. Since this embodiment pertains to a high-k last approach, a gate dielectric layer 20 or interfacial layer made of silicon oxide, a gate material layer 22 made of polysilicon, and a selective hard mask (not shown) could be formed sequentially on the substrate 12, and a pattern transfer process is then conducted by using a patterned resist (not shown) as mask to remove part of the hard mask, part of the gate material layer 22, and even part of the gate dielectric layer 20 through single or multiple etching processes. After stripping the patterned resist, a gate structure 18 composed of a gate dielectric layer 20 and patterned gate material layer 22 is formed on the substrate 12.

Next, at least a spacer 24 is formed on sidewalls of the gate structure 18 and another spacer 26 is formed on sidewalls of the fin-shaped structure 14. In this embodiment, each of the spacers 24, 26 could be a single spacer or a composite spacer, in which the spacer 26 for instance could further include an offset spacer 28 and a main spacer 30. The offset spacer 28 and the main spacer 30 are preferably made of different materials while the offset spacer 28 and main spacer 30 could all be selected from the group consisting of SiO₂, SiN, SiON, and SiCN, but not limited thereto.

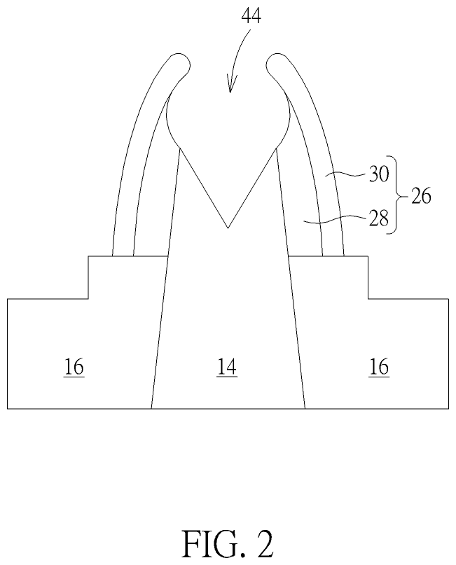

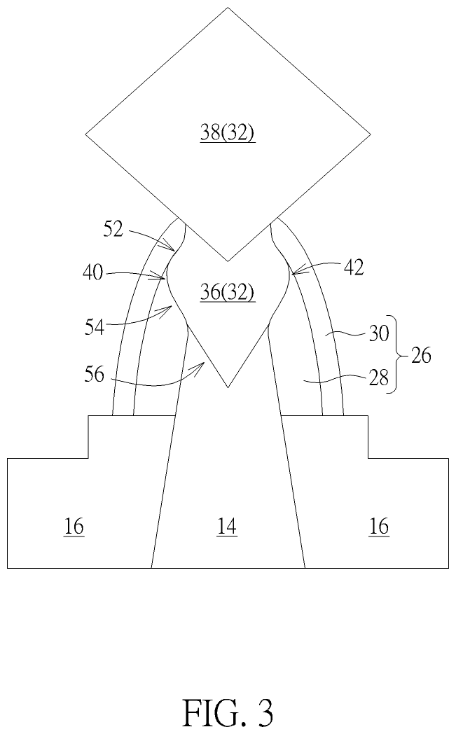

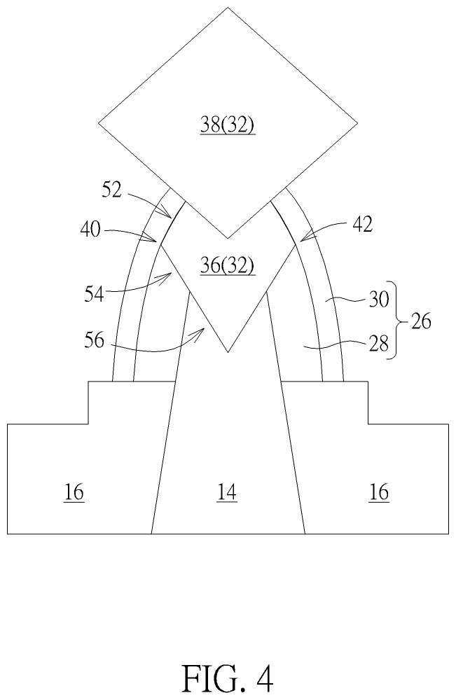

Referring to FIGS. 2-4, FIG. 2 illustrates a method for fabricating a recess taken along the sectional line AA′ of FIG. 1 and FIGS. 3-4 illustrate cross-sectional views for forming an epitaxial layer 32 taken along the sectional line AA′ of FIG. 1. As shown in FIG. 2, one or more dry etching and/or wet etching process is conducted to remove part of the fin-shaped structure 14 along the sidewalls of the spacers 24, 26 to form recesses 44 adjacent to two sides of the gate structure 18. Next, as shown in FIGS. 3 and 4, a selective epitaxial growth (SEG) process is conducted to form an epitaxial layer 32 in the recesses 44. It should be noted that the spacers 24, 26 preferably include stress material and as the aforementioned dry or wet etching process were conducted to form the recesses 44, it would be desirable to adjust fabrication parameters including volume and/or concentration of the gases along with the stress of the spacers 24, 26 so that the neck portion of the recess 44 is expanded outward to form an opening such that the width of the topmost portion of the recess 44 is slightly less than the width of the neck portion of the recess 44.

As shown in the cross-section view, the epitaxial layers 32 preferably share substantially same cross-section shape with the recess. For instance, the cross-section of each of the epitaxial layers 32 could also include a circle, a hexagon, or an octagon depending on the demand of the product. In this embodiment, the epitaxial layers 32 could also be formed to include different materials depending on the type of transistor being fabricated. For instance, if the MOS transistor being fabricated were to be a PMOS transistor, the epitaxial layers 32 could be made of material including but not limited to for example SiGe, SiGeB, or SiGeSn. If the MOS transistor being fabricated were to be a NMOS transistor, the epitaxial layers 32 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layers 32 is preferred to have less or no germanium atom at all to facilitate the formation of silicide afterwards.

According to an embodiment of the present invention, one or more ion implantation process could be conducted to form a source/drain region 34 in part or all of the epitaxial layer 32. According to another embodiment of the present invention, the source/drain region 34 could also be formed insituly during the SEG process. For instance, the source/drain region 34 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain region 34. Moreover, the dopants within the source/drain region 34 could also be formed with a gradient, which is also within the scope of the present invention.

It should be noted that during the formation of the epitaxial layer 32, it would be desirable to adjust the volume and concentration of the gases injected to form a first epitaxial layer 36 and a second epitaxial layer 38 in the aforementioned recess 44, in which the first epitaxial layer 36 and the second epitaxial layer 38 preferably include same material such as SiP and same or different concentrations. Specifically, the bottom surface of each of the first epitaxial layer 36 and the second epitaxial layer 38 from the epitaxial layer 32 includes a V-shape, the angle of the V-shape of the first epitaxial layer 36 is slightly less than the angle of the V-shape of the second epitaxial layer 38, the second epitaxial layer 38 on the top includes a substantially rhombus-shape cross-section, and the left and right neck portions of the first epitaxial layer 36 on the bottom preferably includes a protrusion 40 adjacent to left side of the first epitaxial layer 36 and a protrusion 42 adjacent to right side of the first epitaxial layer 36. Preferably, the protrusions 40, 42 and the first epitaxial layer 36 are formed monolithically at the same time thereby having same material and same concentration.

According to an embodiment of the present invention, the two sidewalls or leftmost sidewall and rightmost sidewall of the protrusions 40, 42 of the first epitaxial layer 36 preferably not exceeding the most protruding left and right portions of the second epitaxial layer 38 above. In other words, the most protruding left and right portions of the second epitaxial layer 38 above preferably overlap the protrusions 40, 42 of the first epitaxial layer 36 completely while the sidewall portions of the protrusions 40, 42 could also be adjusted to have different profiles depending on different fabrication parameters. For instance, as shown in FIG. 3, the sidewall portions of the protrusions 40, 42 could be expanded outward toward two sides of the epitaxial layer 32 to form curved profiles. According to other embodiment of the present invention, as shown in FIG. 4, the sidewall portions of the protrusions 40, 42 could be expanded outward toward two sides of the epitaxial layer 32 to form V-shape profiles and the angle of each of the V-shape profiles is greater than 90 degrees or most preferably between 90-130 degrees.

Viewing from another perspective, the top portion 52, neck portion 54, and bottom portion 56 of the first epitaxial layer 36 from top to bottom could have three different widths, in which the width of the top portion 52 includes a width closer to or even directly contacting the second epitaxial layer 38, the width of the neck portion 54 includes a width measuring between the widest distance or greatest width between the two protrusions 40, 42, and the width of the bottom portion 56 includes a width under the neck portion 54 and closer to the fin-shaped structure 14 underneath. In this embodiment, the width of the top portion 52 closer to the second epitaxial layer 38 is less than the width of the neck portion 54, the width of the bottom portion 56 closer to the fin-shaped structure 14 underneath is also less than the width of the neck portion 54, and the width of the bottom portion 56 is further less than the width of the top portion 52.

Overall, the present invention preferably adjusts fabrication parameters including volume and concentration of gases injected during formation of the epitaxial layer to form a composite epitaxial structure made of dual epitaxial layers or more adjacent to two sides of the gate structure. According to the aforementioned embodiment, the dual layer epitaxial structure includes a lower level first epitaxial layer 36 having a neck portion with two protrusions 40, 42 on two adjacent sides, in which the sidewall profile of the two protrusions could be adjusted depending on the demand of the product to reveal V-shape or round profiles. By using this approach to fabricate epitaxial layers with distinctive protruding neck profiles, it would be desirable to improve overall balance of DC performance for the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a gate structure on a substrate;
forming a first epitaxial layer adjacent to the gate structure, wherein the first epitaxial layer comprises a first protrusion; and
forming a second epitaxial layer on the first epitaxial layer.

2. The method of claim 1, further comprising:
forming a fin-shaped structure on the substrate;
forming the gate structure;
removing the fin-shaped structure to form a recess;
forming the first epitaxial layer in the recess.

3. The method of claim 1, further comprising:
forming the first protrusion on one side of the first epitaxial layer; and
forming a second protrusion on another side of the first epitaxial layer.

4. The method of claim 3, further comprising forming the first protrusion and the second protrusion at the same time.

5. The method of claim 1, wherein a sidewall of the first protrusion comprises a curve.

6. The method of claim 1, wherein a sidewall of the first protrusion comprises a V-shape.

7. The method of claim 1, wherein a bottom surface of the second epitaxial layer comprises a V-shape.

8. The method of claim 1, wherein the first epitaxial layer and the second epitaxial layer comprise sane material.

9. The method of claim 1, wherein the first epitaxial layer and the second epitaxial layer comprise sane concentration.

10. A semiconductor device, comprising:
a gate structure on a substrate;
a first epitaxial layer adjacent to the gate structure, wherein the first epitaxial layer comprises a first protrusion; and
a second epitaxial layer on the first epitaxial layer.

11. The semiconductor device of claim 10, further comprising:
a fin-shaped structure on the substrate;
the gate structure on the fin-shaped structure; and
the first epitaxial layer adjacent to the gate structure.

12. The semiconductor device of claim 10, further comprising:
the first protrusion on one side of the first epitaxial layer; and
a second protrusion on another side of the first epitaxial layer.

13. The semiconductor device of claim 10, wherein a sidewall of the first protrusion comprises a curve.

14. The semiconductor device of claim 10, wherein a sidewall of the first protrusion comprises a V-shape.

15. The semiconductor device of claim 10, wherein a bottom surface of the second epitaxial layer comprises a V-shape.

16. The semiconductor device of claim 10, wherein the first epitaxial layer and the second epitaxial layer comprise sane material.

17. The semiconductor device of claim 10, wherein the first epitaxial layer and the second epitaxial layer comprise sane concentration.
